(19) United States
(12) Patent Application Publication
(10) Pub. No.: US 2004/0126964 A1
(43) Pub. Date: Jul. 1, 2004

(54) Method for fabricating capacitor in semiconductor device

(76) Inventors: Jong-Bum Park, Ichon-shi (KR); Hoon-Jung Oh, Ichon-shi (KR); Kyong-Min Kim, Ichon-shi (KR)

Correspondence Address: BLAKELY SOKOLOFF TAYLOR & ZAFMAN, 12400 WILSHIRE BOULEVARD, SEVENTH FLOOR, LOS ANGELES, CA, 90025, US

(21) Appl. No.: 10/635,811

(22) Filed: Aug. 5, 2003

(30) Foreign Application Priority Data
Dec. 30, 2002 (KR) 2002-86478

(51) Int. Cl. H01L 21/8242; H01L 21/20

(52) U.S. Cl. 438/253; 438/396

(57) ABSTRACT

A method for fabricating a capacitor of a semiconductor device for improving a capacitance and concurrently enhancing a leakage current characteristic and a breakdown voltage characteristic. The method includes the steps of: (a) forming a conductive silicon layer for a bottom electrode on a substrate; (b) nitridating the conductive silicon layer; (c) oxidizing the nitridated conductive silicon layer; (d) forming a silicon nitride layer on a surface of the oxidized layer; (e) forming a dielectric layer on the silicon nitride layer; and (f) forming a top electrode on the dielectric layer.

### FIELD OF INVENTION

The present invention relates to a method for fabricating a semiconductor device; and, more particularly, to a method for fabricating a capacitor in a semiconductor memory device.

### DESCRIPTION OF RELATED ART

Due to large-scale integration of semiconductor devices, for instance, a dynamic random access memory (DRAM), the total area of a memory cell for storing information, has rapidly decreased.

Particularly, the reduced memory cell area reduces the available area for a capacitor in the memory cell. The reduced memory cell area also reduces a sensing margin and a sensing speed. Furthermore, this reduction of the memory cell area lessens tolerance to soft errors, of the type created by a particles.

A capacitance C of a capacitor is defined by the following equation.

C=ε×As/d Eq. 1

Herein, ε is a dielectric constant; As is an effective surface area of a electrode; d is a distance between the electrodes.

Based on the Eq. 1, there are three approaches for increasing the capacitance of the capacitor: the first approach is to increase the effective surface area of the electrode; the second approach is to decrease a thickness of a dielectric substance; and the third approach is to increase the dielectric constant.

Among the three approaches, the first approach is initially considered for increasing the capacitance of the capacitor. As mentioned above, in the first approach, the effective surface area of the electrode is increased. Thus, the capacitor should be formed with a specific three-dimensional structure such as a concave structure, a cylinder structure, a multiply layered pin structure and so on. However, this approach has become limited due to a trend of ultra large-scale integration of a semiconductor device.

The second approach is to decrease the thickness of the dielectric substance to minimize a distance d between the electrodes. This approach is also faced with a limitation because leakage currents are increased due to the fact that the thickness of the dielectric substance is decreased.

Therefore, current research and development focuses on how to increase the capacitor capacitance by increasing the dielectric constant. Most capacitors have a so-called nitride-oxide (NO) structure wherein a silicon oxide layer and a silicon nitride layer are used for the dielectric layer. However, the dielectric layer for the capacitor is made of a material having a high dielectric constant as Ta₂O₅, (Ba,Sr)TiO₃ (BST) and the like or a ferroelectric material as (Pb,Zr)TiO₃ (PZT), (Pb,La)(Zr,Ti)O₃ (PLZT), SrBi₂Ta₂I₉ (SBT), Bi₄—XLaXTi₃O₁₂ (BLT) and the like.

FIG. 1A to FIG. 1C are cross-sectional views showing a conventional method for fabricating a capacitor with a cylinder structure.

As shown in FIG. 1A, an active region 11 is formed in a substrate 10. After an inter-insulation layer 12 is formed on substrate 10, a contact hole is formed for contacting the active region 11 of the substrate 10 by passing through the inter-insulation layer 12. The contact hole is buried with a conductive metal to form a contract plug 13. Then, an insulation layer 14 is formed with the same height as that of the capacitor.

The insulation layer 14 is selectively etched to expose the contact plug 13 to form a trench. A bottom electrode 15 is formed with a conductive silicon layer and is deposited along a profile containing the trench. Then, the insulation layer 14 is eliminated.

As shown in FIG. 1B, a silicon nitride layer 16 is formed with a thickness ranging from about 5 Å to about 50 Å on the bottom electrode 15 by using ammonia (NH₃) plasma.

Referring to FIG. 1C, a dielectric layer 17 is formed on the silicon nitride layer 16, and a top electrode is formed thereon by employing the conductive layer.

Herein, the silicon nitride layer 16 is formed for preventing formation of a silicon oxide layer during a subsequent high thermal process. If the silicon oxide layer having a low dielectric constant is formed above and below the dielectric layer, the dielectric characteristic of the capacitor is deteriorated.

The silicon nitride layer 16 is not uniformly formed on a surface of the bottom electrode 15 because the bottom electrode 15 has a cylinder structure. Hence, the silicon oxide layer is excessively formed on a portion of the bottom electrode 15 on which the silicon nitride layer 16 is not formed. As a result, there arises a problem that the capacitance is decreased on some portions of the bottom electrode 15 due to the excessive formation of the unintended silicon oxide formation.

In addition, the nitride layer for preventing a reduction of the capacitance creates a problem because a current leakage in the capacitor is increased and a breakdown voltage is decreased.

### SUMMARY OF INVENTION

It is, therefore, an object of the present invention to provide a method of fabricating a capacitor of a semiconductor device to improve a capacitance and concurrently enhance a leakage current characteristic and a breakdown voltage characteristic.

In accordance with an aspect of the present invention, there is provided the method for fabricating the capacitor of a semiconductor device, including the steps of: (a) forming a conductive silicon layer for a bottom electrode on a substrate; (b) nitridating the conductive silicon layer; (c) oxidizing the nitridated conductive silicon layer; (d) forming a silicon nitride layer on a surface of the oxidized layer; (e) forming a dielectric layer on the silicon nitride layer; and (f) forming a top electrode on the dielectric layer.

### BRIEF DESCRIPTION OF THE DRAWINGS

The above and other objects and features of the present invention will become apparent from the following description of preferred embodiments taken in conjunction with the accompanying drawings, in which:

FIG. 1A to FIG. 1C are cross-sectional views showing a conventional method for fabricating a capacitor with a cylinder structure;

FIG. 2A to FIG. 2E are cross-sectional views showing a method for fabricating a capacitor of a semiconductor device in accordance with a preferred embodiment of the present invention; and

FIG. 3A to FIG. 3C are graphs showing effectively established characteristics of the capacitor fabricated in accordance with the present invention.

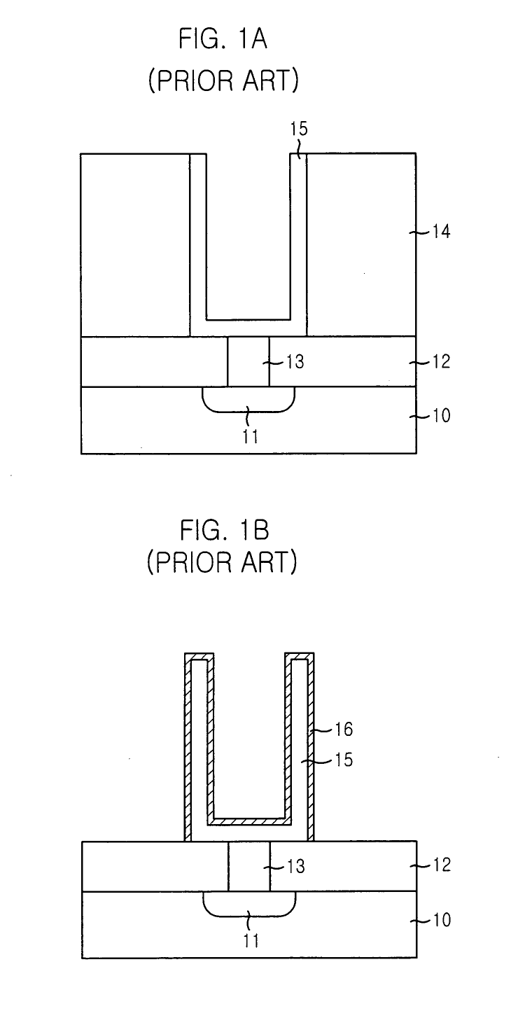

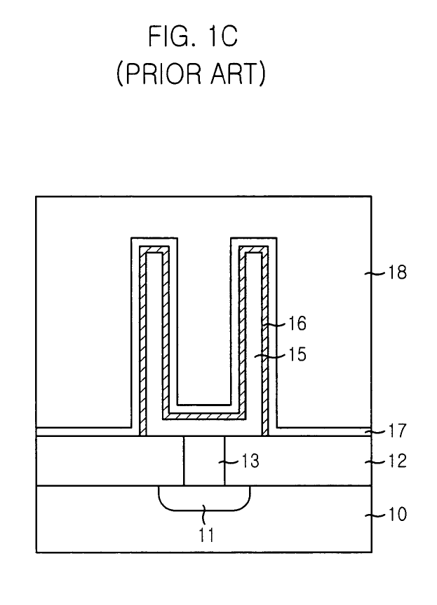

### DETAILED DESCRIPTION OF THE INVENTION

Hereinafter, a capacitor of a semiconductor device fabricated in accordance with the present invention will be described in detail referring to the accompanying drawings.

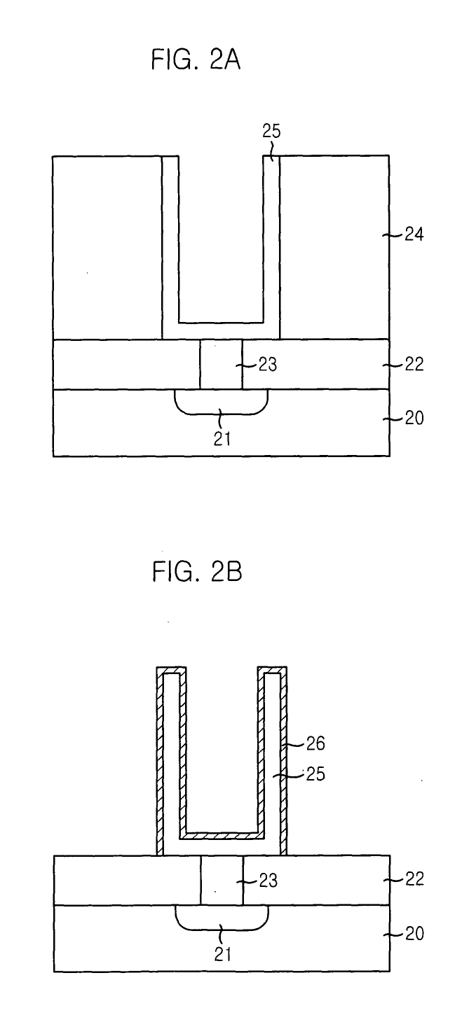

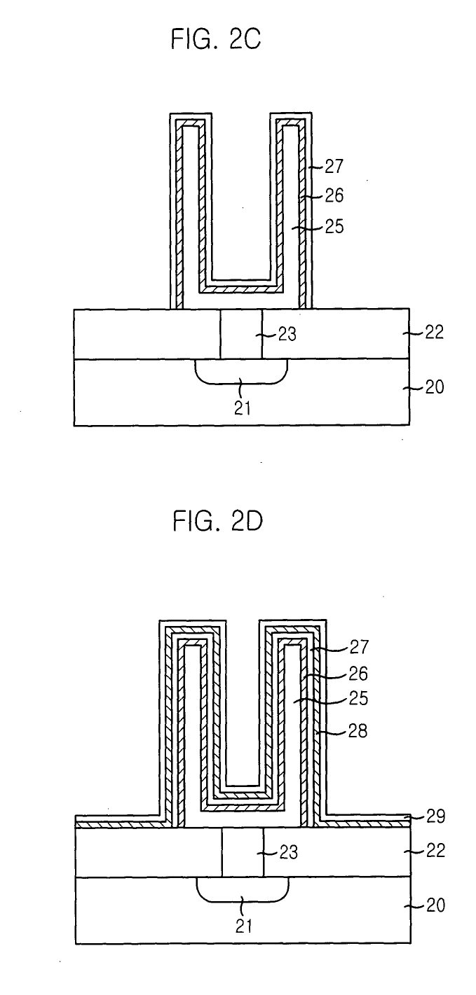

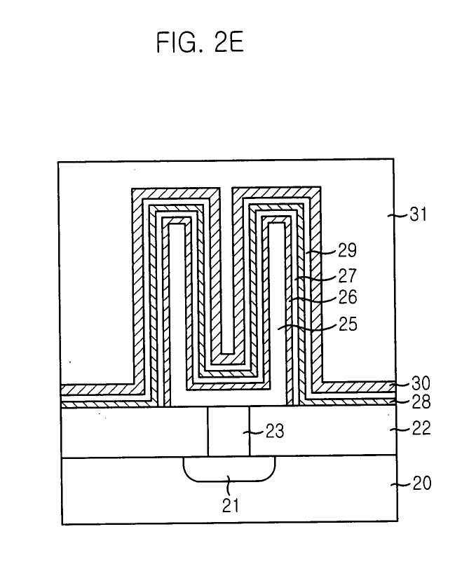

FIGS. 2A to 2E are cross-sectional views showing a method for fabricating a capacitor of a semiconductor device in accordance with a preferred embodiment of the present invention.

As shown in FIG. 2A, an active region 21 is formed in a substrate 20. After an inter-insulation layer 22 is formed on a substrate 20, a contact hole is formed by passing through the inter-insulation layer 22 so that a plug 23 contacts the active region 21 of the substrate 20. The contact hole is filled with a conductive metal to form the plug 23. Hereinafter, this plug 23 is referred to as a contact plug. The inter-insulation layer 22 is formed with an oxide layer or a thermal oxide layer. The oxide layer is made of a material selected from a group consisting of undoped-silicate glass (USG), phosphorus-silicate glass (PSG), boron-phosphorus-silicate glass (BPSG), high density plasma (HDP), spin on glass (SOG) and tetra-ethyl-ortho silicate (TEOS). The thermal oxide layer is formed by oxidizing a silicon substrate at a temperature ranging from about 600° C. to about 1100° C.

An insulation layer 24 is formed in the same height of the capacitor. The insulation layer 24 is formed with a thickness ranging from about 3000 Å to about 5000 Å by employing an oxide layer or a thermal oxide layer. Herein, the oxide layer and the thermal oxide layer are formed with the same method as described above.

Next, the insulation layer 24 is selectively etched until the contact plug 23 is exposed so that a trench is formed. A bottom electrode 25 is formed along a profile containing the trench. At this time, the bottom electrode 25 is made of polysilicon.

Describing in further detail the bottom electrode 25 formation, an impurity doped polysilicon layer is deposited with a thickness ranging from about 50 Å to about 300 Å. An impurity non-doped polysilicon layer is subsequently deposited to a thickness ranging from about 50 Å to about 300 Å, and phosphine (PH₃) is then doped thereon in an atmosphere of nitrogen (N₂).

Referring to FIG. 2B, the insulation layer 24 for a capacitor is removed and a SC-1 cleaning process is performed thereafter. At this time, the hydrofluoric acid (HF) or buffer oxide etchant (BOE) is used in the SC-1 cleaning process to remove the insulation layer 24. The SC-1 cleaning process also employs ammonium hydroxide (NH₄OH), hydrogen peroxide (H₂O₂) and H₂O. As a result of the SC-1 cleaning process, a first silicon oxide layer 26 of which thickness ranges from about 5 Å to about 10 Å is formed in a manner to encompass the bottom electrode 25. When the SC-1 cleaning process is performed, the first silicon oxide layer 26, which is a thin native oxide layer formed during the SC-1 cleaning process, is formed in a thickness ranging about 5 Å to about 10 Å.

Afterwards, the polysilicon layer formed as the bottom electrode 25 is doped with PH₃ in an atmosphere of N₂. At this time, the doping is performed at a temperature ranging from about 500° C. to about 800° C. and a pressure ranging from about 0.1 Torr to about 100 Torr. This doping is to minimize a depletion phenomenon occurring during operation of the capacitor.

Then, a thermal treatment process is performed. This process densifies the first silicon oxide layer 26 to a greater extent and minimizes oxidization of the bottom electrode 25 during the thermal treatment process performed with use of a furnace in an atmosphere of N₂O after a dielectric layer deposition process.

As shown in FIG. 2C, a first silicon nitride layer 27 is uniformly formed by the thermal treatment process which is carried out in a pressure ranging from about 10 Torr to about 100 Torr with use of a furnace.

Referring to FIG. 2D, a second silicon oxide layer 28 is formed on the first silicon nitride layer 27 by exposing the substrate 20 to an atmosphere. At this time, a thickness of the second silicon oxide layer 28 ranges from about 1 Å to about 5 Å. The second silicon oxide layer 28 is a native oxide layer generated when the substrate 20 is exposed in the atmosphere.

A second silicon nitride layer Si₃N₄ 29 is deposited by using a dichlorosilane (DCS) source in an atmosphere of NH₃ and at a pressure ranging from about 1 Torr to about 10 Torr. Herein, the first and the second silicon nitride layers 27 and 29 are formed in a thickness ranging from about 5 Å to about 20 Å.

As shown in FIG. 2E, on the second silicon nitride layer 29, a dielectric layer 30 is formed in a thickness ranging from about 30 Å to about 100 Å. At this time, a temperature for forming the dielectric layer 30 ranges from about 300° C. to about 500° C. Also, the dielectric layer 30 is formed under a pressure ranging from about 0.1 Torr to about 1.0 Torr. For improving device characteristics and crystallization of the dielectric layer 30, a thermal treatment process is performed in an atmosphere of N₂O or O₂ with use of a furnace. At this time, the thermal treatment process is carried out at a temperature ranging from about 500° C. to about 800° C.

In case of using Ta₂O₅ for forming the dielectric layer 30, the dielectric layer is formed by using Ta(C₂H₅O)₅ and O₂ as a source and a reaction gas. At this time, the dielectric layer 30 formation is carried out at a temperature ranging from about 300° C. to about 500° C. and a pressure ranging from about 0,1 Torr to about 1.0 Torr. Also, a thickness of the dielectric layer 30 ranges from about 20 Å to about 100 Å. The dielectric layer 30 is made of a material selected from a group of substances having a high dielectric constant such as Al₂O₃, HfO₂, BST and so on or a group of ferroelectric substances such as PZT, PLZT, BLT and so on.

Next, a top electrode 31 is formed on the dielectric layer 30 by using a conductive layer. The top electrode 31 is formed by depositing a TiN layer through the use of chemical vapor deposition (CVD) and then a polysilicon layer on the top electrode 31.

The first silicon nitride layer 27, the second silicon oxide layer 28 and the second silicon nitride layer 29 are formed between the dielectric layer 30 and the bottom electrode 29 by employing the process as described above. This process is called a second effective furnace nitridation (EF2N) process. Herein, the first and second silicon nitride layers 27 and 29 is to prevent the oxide layer from being excessively generated in order to secure a predetermined capacitance, and the second silicon oxide layer 28 is for improving a leakage current characteristic and a breakdown voltage characteristic.

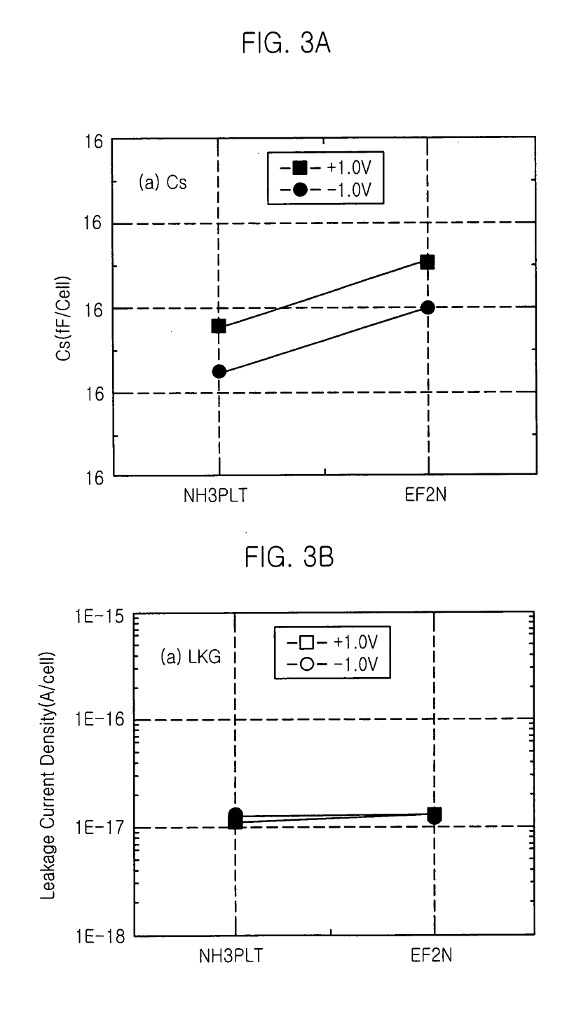

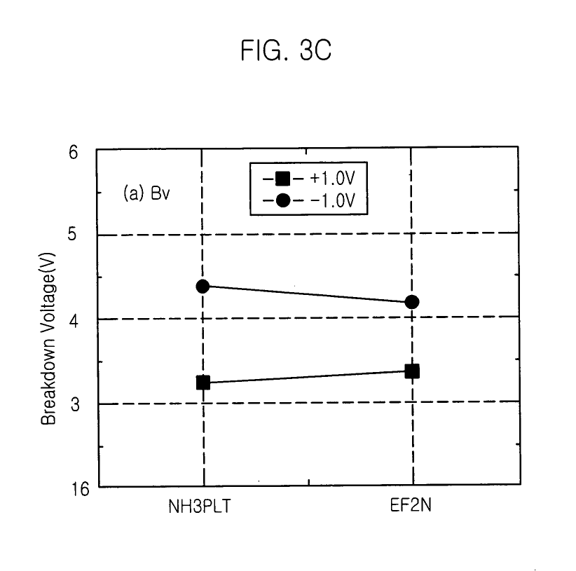

FIGS. 3A to 3C are graphs showing effectively established characteristics of the capacitor fabricated in accordance with the present invention.

Especially, the graphs present characteristics about capacitance Cs, leakage current and breakdown voltage of the capacitors obtained under a conventional NH₃ plasma process for suppressing the formation of the oxide layer on an interface between dielectric layers and the aforementioned EF2N process for suppressing the formation of the oxide layer on interface between the bottom electrode and the dielectric layer.

Referring to FIGS. 3A and 3B, compared with the capacitance of a capacitor fabricated by the conventional NH₃ plasma process (NH₃ PLT), the capacitance Cs is improved by using the EF2N process. In addition, characteristics of leakage current and breakdown voltage are constantly maintained.

While the present invention has been described with respect to the particular embodiments, it will be apparent to those skilled in the art that various changes and modification may be made without departing from the spirit and scope of the invention as defined in the following claims.

What is claimed is:

1. A method for fabricating a capacitor of a semiconductor device, comprising the steps of:
(a) forming a conductive silicon layer for a bottom electrode on a substrate;
(b) nitridating the conductive silicon layer;
(c) oxidizing the nitridated conductive silicon layer;
(d) forming a silicon nitride layer on a surface of the oxidized layer;
(e) forming a dielectric layer on the silicon nitride layer; and
(f) forming a top electrode on the dielectric layer.

2. The method as recited in claim 1, wherein at the step (c), a native oxide layer is used.

3. The method as recited in claim 2, wherein the native oxide layer is formed in a thickness ranging from about 1 Å to about 5 Å.

4. The method as recited in claim 3, wherein at the step (b), a thermal treatment process is carried out in an atmosphere of NH₃ gas and at a pressure ranging from about 10 Torr to about 100 Torr.

5. The method as recited in claim 4, wherein the silicon nitride layer is formed by using a source of dichlorosilane (DCS) in an atmosphere of NH₃ gas and at a pressure ranging from about 1 Torr to about 10 Torr.

6. The method as recited in claim 3, wherein the dielectric layer is comprised of a material having one of a high dielectric constant and being a ferroelectric substance.

7. The method as recited in claim 6, wherein the material is one selected from a group of Ta₂O₅, Al₂O₃, HfO₂, (Ba,Sr)TiO₃ (BST), (Pb,Zr)TiO₃ (PZT), (Pb,La)(Zr,Ti)O₃ (PBZT) and Bi₄—XlaXTi₃O₁₂ (BLT).
